(19) United States
(12) Patent Application Publication
(10) Pub. No.: US 2025/0275280 A1
(43) Pub. Date: Aug. 28, 2025

(54) IMAGE SENSOR

(71) Applicant: SAMSUNG ELECTRONICS CO., LTD., Suwon-si (KR)

(72) Inventors: Seungsik KIM, Suwon-si (KR); Yongjun Kim, Suwon-si (KR); Sunhee Yun, Suwon-si (KR); Sol Yoon, Suwon-si (KR)

(73) Assignee: SAMSUNG ELECTRONICS CO., LTD., Suwon-si (KR)

(21) Appl. No.: 19/059,972

(22) Filed: Feb. 21, 2025

(30) Foreign Application Priority Data
Feb. 22, 2024 (KR) 10-2024-0026050

(51) Int. Cl. H10F 39/00

(52) U.S. Cl. CPC H10F 39/807; H10F 39/8037; H10F 39/811

(57) ABSTRACT

An image sensor including pixels includes an isolation layer that divides the pixels from each other, a photoelectric conversion device, a floating diffusion area that receives a charge from the photoelectric conversion device, a source follower transistor that outputs a pixel signal corresponding to the charge from the floating diffusion area, and a connection line that connects the floating diffusion area to a gate of the source follower transistor. The connection line extends from the floating diffusion area to the gate of the source follower transistor, contacts each of the gate of the source follower transistor and the floating diffusion area, and overlaps with a portion of the isolation layer.

### CROSS-REFERENCE TO RELATED APPLICATION

This application claims priority under 35 U.S.C. § 119 to Korean Patent Application No. 10-2024-0026050 filed on Feb. 22, 2024, in the Korean Intellectual Property Office, the disclosure of which being incorporated by reference herein in its entirety.

### BACKGROUND

Embodiments of the present disclosure described herein relate to an image sensor.

In the semiconductor memory device, the image sensor may convert an optical signal including image information of a subject into an electrical signal. A charge coupled device (CCD) image sensor and a complementary metal oxide semiconductor (CMOS) image sensor have been extensively used as the image sensor. Recently, with the development of a computer industry and a communication industry, image sensors having improved performance are increasingly demanded in various electronic devices, such as digital cameras, camcorders, personal communication systems (PCS), game devices, security cameras, medical micro-cameras, and mobile phones.

The resolution of the image sensor may be increased by providing a larger number of pixels in the same area. However, when the large number of pixels are provided in the same area, there may limits to the physical size of the pixel and limits to a design rule of components (e.g., a plurality of transistors, capacitors, and signal lines for connecting the transistors, capacitors, etc.) in the pixel, and these limitations may limit how small the pixels may be made. In particular, a parasitic capacitance of signal lines adjacent to each other in a pixel causes the deterioration of the image sensor. Accordingly, a technology of minimizing the defect, which may be caused between the components in the pixel, and efficiently using the inner space in the pixel needs to be developed.

### SUMMARY

It is an aspect to provide an image sensor employing an interconnection structure to minimize coupling between a floating diffusion node and lines adjacent to the floating diffusion node, and to improve a degree of freedom in space for an arrangement of the lines.

According to an aspect of one or more embodiments, there is provided an image sensor including a plurality of pixels, the image sensor comprising an isolation layer configured to divide the plurality of pixels from each other; at least one photoelectric conversion device; at least one floating diffusion area configured to receive a charge from the at least one photoelectric conversion device; a source follower transistor configured to output a pixel signal corresponding to the charge from the at least one floating diffusion area; and a connection line configured to connect the at least one floating diffusion area to a gate of the source follower transistor. The connection line extends from the at least one floating diffusion area to the gate of the source follower transistor, contacts each of the gate of the source follower transistor and the at least one floating diffusion area, and overlaps with at least a portion of the isolation layer.

According to another aspect of one or more embodiments, there is provided an image sensor having at least two pixel groups, each including a plurality of pixels, the at least two pixel groups being arranged in a form of a matrix, the image sensor comprising an isolation layer configured to divide the plurality of pixels from each other; a plurality of photoelectric conversion devices provided in the plurality of pixels, respectively; at least one floating diffusion area configured to receive a charge from each of the plurality of photoelectric conversion devices; at least one reset transistor connected to the at least one floating diffusion area to reset the at least one floating diffusion area to a pixel voltage; a source follower transistor configured to output a pixel signal corresponding to the charge from the at least one floating diffusion area; and a connection line configured to connect the at least one floating diffusion area to a gate of the source follower transistor. The connection line extends in one line without being separated into segments to connect the at least one floating diffusion area, the gate of the source follower transistor, and a drain of the at least one reset transistor to each other, contacts each of the at least one floating diffusion area, the gate of the source follower transistor, and the drain of the at least one reset transistor, and overlaps with at least a portion of the isolation layer.

According to yet another aspect of one or more embodiments, there is provided an image sensor including at least one pixel group provided in a form of a matrix and including first to eighth pixels, the image sensor comprising first to eighth photoelectric conversion devices provided in the first to eighth pixels, respectively; a floating diffusion area configured to receive a charge from the first to eighth photoelectric conversion devices; first to third reset transistors connected to the floating diffusion area to reset the floating diffusion area to a pixel voltage; a source follower transistor connected to the floating diffusion area to output a pixel signal corresponding to the charge from the floating diffusion area; a selection transistor connected to the source follower transistor, to output the pixel signal to an output node; and a connection line configured to connect the source follower transistor to the floating diffusion area. The floating diffusion area includes first to eighth floating diffusion areas provided in the first to eighth pixels, respectively, and the connection line contacts with at least one of the first to eighth floating diffusion areas and a gate of the source follower transistor to connect the gate of the source follower transistor to the at least one of the first to eighth floating diffusion areas.

### BRIEF DESCRIPTION OF THE FIGURES

The above and other aspects will become apparent by describing in detail embodiments thereof with reference to the accompanying drawings, in which:

FIG. 1 is a block diagram of an image sensor according to an embodiment;

FIG. 2 is a circuit diagram of a pixel in an image sensor, according to an embodiment;

FIG. 3A is a plan view illustrating one pixel group of an image sensor, and FIG. 3B is a plan view illustrating components of FIG. 3A without some components of FIG. 3A for convenience of explanation, according to various embodiments;

FIG. 4 is a cross-sectional view taken along line A-A′ of FIG. 3A;

FIGS. 5A and 5B are cross-sectional views taken along the lines B-B′ and C-C′ of FIG. 3A, respectively, in which a part of an image device including a connection line is illustrated;

FIG. 6 is cross-sectional views corresponding to parts P1 and P2 of FIG. 5B, and illustrates that first and second protective layers are provided at lower and upper sides of the connection line, respectively; according to an embodiment;

FIG. 7 is a cross-sectional view corresponding to line A-A′ of FIG. 3A;

FIG. 8A and FIG. 8B are cross-sectional views corresponding to line B-B′ and line C-C′ of FIG. 3A, respectively;

FIG. 9 is a cross-sectional view corresponding to parts P3 and P4 of FIG. 8B;

FIG. 10A is a plan view illustrating a pixel group including eight pixels in an image sensor according to an embodiment, and FIG. 10B is a plan view illustrating components of FIG. 10A without some components, for convenience of explanation, according to an embodiment;

FIG. 11 is a cross-sectional view taken along the line A-A′ of FIG. 10A;

FIGS. 12A and 12B are cross-sectional views taken along the line B-B′ and the line C-C′ of FIG. 10A, respectively;

FIG. 13 is cross-sectional views corresponding to parts P5 and P6 of FIG. 12B;

FIG. 14A is a plan view illustrating four pixel groups of an image sensor according to an embodiment, and FIG. 14B is a plan view illustrating components of FIG. 14A without some components for convenience of explanation, according to an embodiment;

FIG. 15 is a cross-sectional view taken along the line A-A′ of FIG. 14A; and

FIGS. 16A and 16B are cross-sectional views taken along the line B-B′ and the line C-C′ of FIG. 14A, respectively.

### DETAILED DESCRIPTION

Hereinafter, various embodiments will be described clearly and in detail to the extent that an ordinary person skilled in the art to which the present disclosure pertains may easily reproduce the present disclosure.

It will be understood that when an element or layer is referred to as being “over,” “above,” “on,” “below,” “under,” “beneath,” “connected to”, “contacted with”, or “coupled to” another element or layer, it can be directly over, above, on, below, under, beneath, connected, contacted with, or coupled to the other element or layer or intervening elements or layers may be present.

Hereinafter, exemplary embodiments will be described in more detail with reference to accompanying drawings.

Various semiconductor devices have circuits having lines including a plurality of transistors. These lines may be formed of conductive materials at various layers and may be interconnected to each other in various forms. According to various embodiments, the lines in various forms have an interconnection structure which minimizes the formation of parasitic capacitance between adjacent lines.

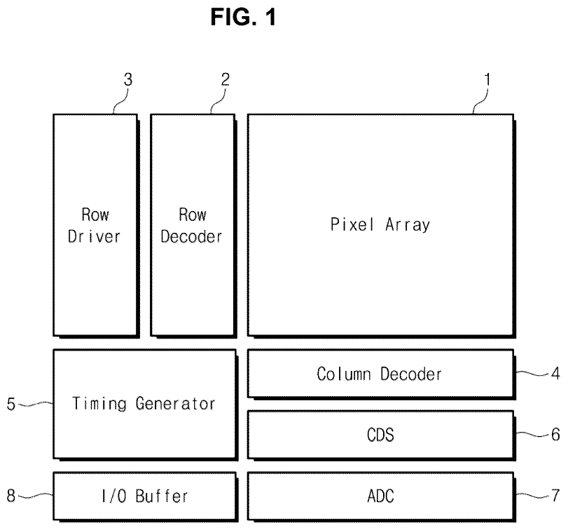

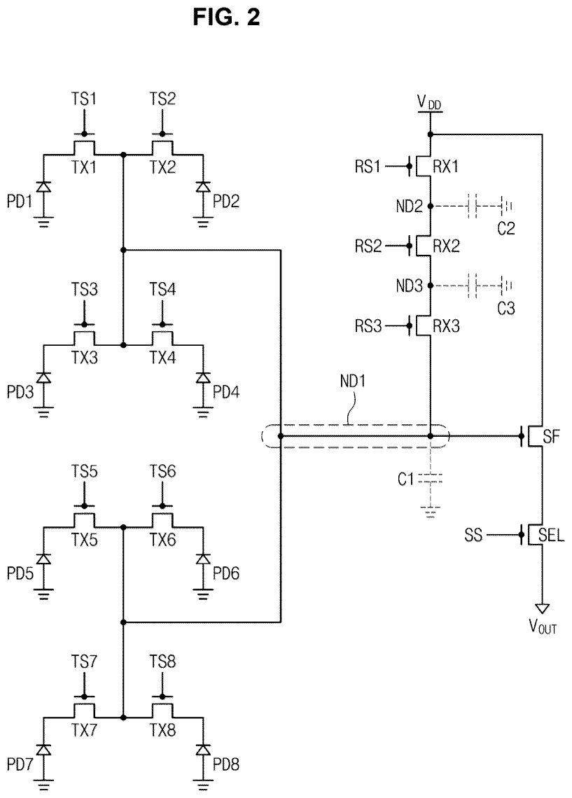

FIG. 1 is a block diagram of an image sensor according to an embodiment. FIG. 2 is a circuit diagram of a pixel in an image sensor, according to an embodiment.

Referring to FIG. 1, an image sensor may include a pixel array 1, a row decoder 2, a row driver 3, a column decoder 4, a timing generator 5, a correlated double sampler (CDS), an analog-to-digital converter (ADC) 7, and an input/output buffer (I/O buffer) 8.

The pixel array 1 may be a complementary metal oxide semiconductor image sensor (CIS) which converts an optical signal into an electrical signal. The pixel array 1 may include a plurality of pixel groups arranged in two dimensions. The pixel array 1 may include, for example, a plurality of pixel groups arranged in a matrix shape. Each pixel group includes at least one pixel, and when one pixel group includes a plurality of pixels, a plurality of pixels may also be arranged in a matrix shape.

The pixel array 1 may be driven in response to a plurality of driving signals, such as a pixel selecting signal, a reset signal, and a charge transfer signal, which are received from the row driver 3. In addition, the converted electrical signal is provided to the correlated double sampler 6.

The row driver 3 provides a plurality of driving signals for driving a plurality of unit pixels of the pixel array 1, based on a decoding result from the row decoder 2. When the pixels are arranged in a matrix form as described above, the driving signals may be provided for each row.

The timing generator 5 provides a timing signal and a control signal to the row decoder 2 and the column decoder 4.

The correlated double sampler (CDS) 6 receives, holds, and samples the electrical signal generated from the pixel array 1. The correlated double sampler 6 samples a specific noise level and a signal level based on the electrical signal doubly, and outputs a difference level corresponding to the difference between the noise level and the signal level.

The analog-to-digital converter (ADC) 7 converts an analog signal corresponding to the difference level, which is output from the correlated double sampler 6, into a digital signal and outputs the digital signal.

The input/output buffer (I/O Buffer) 8 latches the digital signal, and the latched digital signal is sequentially output to an image signal processing unit (not illustrated) depending on the decoding result from the column decoder 4.

Referring to FIG. 2, one pixel group includes at least one pixel, and photoelectric conversion devices PD1, PD2, . . . , and PD8 provided for each pixel and a plurality of transistors.

The plurality of transistors may include a transfer transistor, a reset transistor, a source follower transistor (SF), and a selection transistor (SEL). According to an embodiment, a plurality of transfer transistors may be provided, and, for example, may include first to eighth transfer transistors TX1, TX2, . . . , and TX8. The reset transistor may include a first reset transistor RX1, a second reset transistor RX2, and a third reset transistor RX3.

Each of the photoelectric conversion devices PD1, PD2, . . . , and PD8 may generate electric charges based on the intensity of light incident to the photoelectric conversion devices PD1, PD2, . . . , and PD8. For example, each of the photoelectric conversion devices PD1, PD2, . . . , and PD8, which may be, for example, a P-N junction diode, may generate charges, that is, electrons, which are negative charges, and holes which are positive charges, in proportion to an amount of received light. Each of the photoelectric conversion devices PD1, PD2, . . . , and PD8 may correspond to at least one of a photo transistor, a photo gate, a pinned photo diode (PPD), or a combination thereof.

According to an embodiment, the pixel group may include the plurality of pixels sharing one floating diffusion node together. In FIG. 2, the floating diffusion node is indicated by a first node “ND1”. For example, the pixel group may include the plurality of pixels connected to the floating diffusion node. According to an embodiment, one pixel group may include at least one photoelectric conversion device. For example, one pixel group may include two, four, eight, or nine pixels.

According to an embodiment, it is illustrated that eight photoelectric conversion devices are provided, that is, the first to eighth photoelectric conversion devices PD1, PD2, . . . , and PD8 are provided by way of example. The transfer transistors TX1, TX2, . . . , and TX8 may transfer charges, which are generated from the photoelectric conversion devices PD1, PD2, . . . , and PD8, to the first node ND1, in response to transfer control signals TS1, TS2, . . . , and TS8.

The first node N1 may have a junction capacitor C1. The first node ND1 may store electric charges received from the photoelectric conversion devices PD1, PD2, . . . , and PD8 through the transfer transistors TX1, TX2, . . . , and TX8. The first node ND1 may be connected to a second node ND2 and/or a third node ND3 by turning on and/or turning off the second reset transistor RX2 and the third reset transistor RX3. Mutually different conversion gains may be provided depending on the connection of the first node ND1, the second node ND2, and/or the third node ND3.

The source follower transistor SF may correspond to a buffer amplifier. The source follower transistor SF may also be referred to as a driving transistor. Since the gate of the source follower transistor SF is connected to the first node ND1, the voltage of the first node ND1 may correspond to the gate voltage of the source follower transistor SF. In other words, the source follower transistor SF may amplify the gate voltage value, which is changed based on the charge transmitted to the first node ND1, and output the amplified gate voltage value in the form of a pixel signal V_{OUT}.

The selection transistor SEL may have a drain node connected to a source node of the source follower transistor SF and output a pixel signal V_{OUT} through the output node, in response to the selection signal SS.

The first to third reset transistors RX1, RX2, and RX3 may be controlled in response to reset control signals RS1, RS2, and RS3, respectively.

The first reset transistor RX1 may be connected to a power supply voltage node V_{DD}. The second reset transistor RX2 may be connected in series to the first reset transistor RX1 through the second node ND2. A parasitic capacitor C2 may be formed at the second node ND2. The second reset transistor RX2 may connect the second node ND2 to the third node ND3. The third reset transistor RX3 may be connected in series to the second reset transistor RX2 through the third node ND3. The third reset transistor RX3 may connect the first node ND1 to the third node ND3. A parasitic capacitor C3 may be formed at the third node ND3.

When the third reset transistor RX3 is turned on, the first node ND1 and the third node ND3 may be connected to each other. When the second reset transistor RX2 and the third reset transistor RX3 are turned on, the first node ND1 may be connected to the second node ND2 and the third node ND3. When the first reset transistor RX1, the second reset transistor RX2, and the third reset transistor RX3 are turned on, the first node ND1 may be connected to a power supply voltage V_{DD}. When the first reset transistor RX1, the second reset transistor RX2, and the third reset transistor RX3 are turned on, the first node ND1 may be reset by the voltage across the pixel voltage node.

The second reset transistor RX2 and the third reset transistor RX3 may perform a triple conversion gain (TCG) operation.

For example, in a high conversion gain (HCG) mode, the voltage across the first node ND1 may be sampled through the source follower transistor SF, in the state in which the first reset transistor RX1, the second reset transistor RX2, and the third reset transistor RX3 are turned off. In this case, the reset voltage after the first node ND1 is reset by the voltage across the pixel voltage node and the pixel voltage after the charges generated from the photoelectric conversion devices PD1, PD2, . . . , and PD8 are transmitted to the first node ND1, respectively, may be sampled.

In a middle conversion gain (MCG) mode, the voltage across the first node ND1 may be sampled through the source follower transistor SF in the state in which the first reset transistor RX1 and the second reset transistor RX2 are turned off and the third reset transistor RX3 is turned on. Since the voltage of the first node ND1 is sampled in the state in which the first node ND1 and the third node ND3 are connected, a conversion gain lower than that of the HCG mode may be provided. In this case, in the state in which the third node ND3 is connected to the first node ND1, the reset voltage after the first node ND1 is reset by the voltage of the pixel voltage node and the pixel voltage after the charges generated from the photoelectric conversion devices PD1, PD2, . . . , and PD8 are transmitted to the first node ND1 may be sampled, respectively.

In a low conversion gain (LCG) mode, the voltage across the first node ND1 may be sampled through the source follower transistor SF in the state in which the first reset transistor RX1 is turned off and the second reset transistor RX2 and the third reset transistor RX3 are turned on. Since the voltage across the first node ND1 is sampled in the state in which the first node ND1, the second node ND2, and the third node ND3 are connected to each other, a conversion gain lower than that of the MCG mode may be provided. In this case, in the state in which the second node ND2 and the third node ND3 are connected to the first node ND1, the reset voltage after the first node ND1 is reset by the voltage across the pixel voltage node and the pixel voltage after the charges generated from the photoelectric conversion devices PD1, PD2, . . . , and PD8 are transmitted to the first node ND1 may be sampled, respectively.

According to various embodiments, the image sensor may flexibly provide the conversion gain mode. For example, in the state in which a higher conversion gain is to be used, the image sensor may provide the HCG mode, for example, when the ambient illuminance is low, and the LCG mode may be provided, for example, when the ambient illuminance is high. In some embodiments, the image sensor may generate a high dynamic range (HDR) image, based on pixel signals sampled in each of the HCG mode, the MCG mode, and the LCG mode.

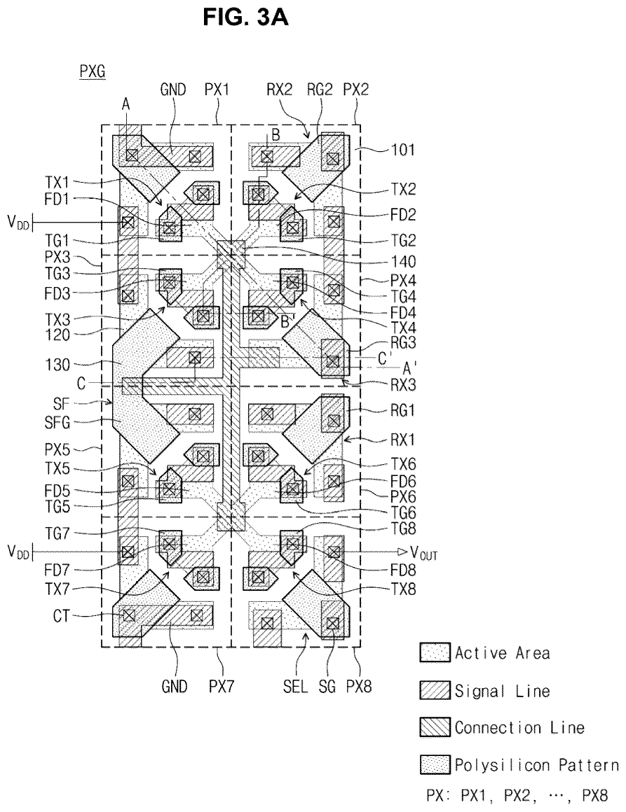

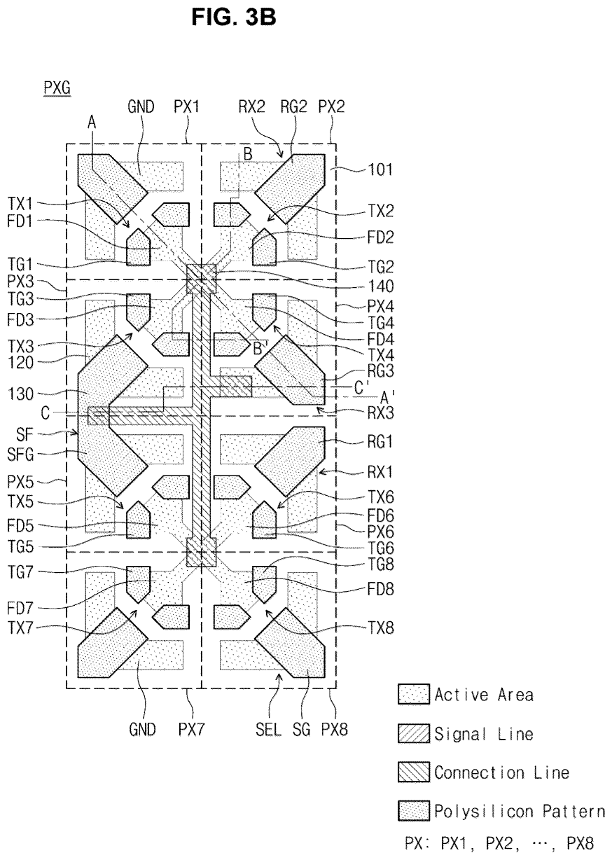

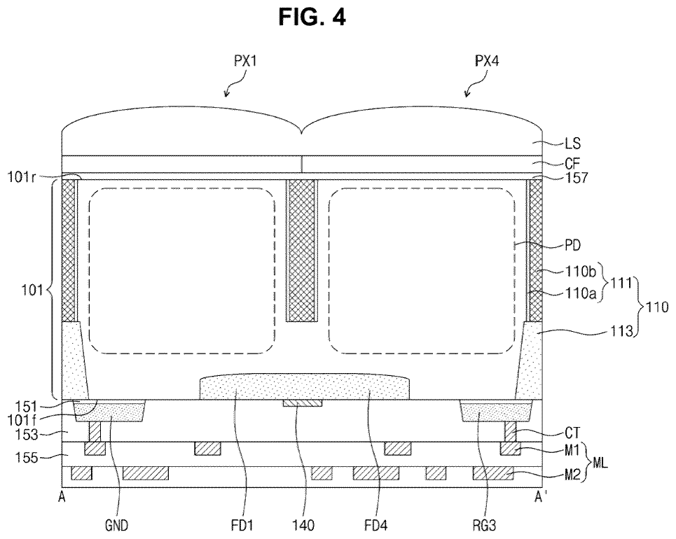

FIG. 3A is a plan view illustrating one pixel group of an image sensor, and FIG. 3B is a plan view illustrating components of FIG. 3A without some components of FIG. 3A for convenience of explanation, according to an embodiment. FIG. 4 is a cross-sectional view taken along line A-A′ of FIG. 3A.

Referring to FIGS. 3A, 3B, and 4, the image sensor may include a semiconductor substrate 101 and a pixel group PXG provided for the semiconductor substrate 101. One pixel group PXG may be a minimum unit repeatedly arranged in the form of a matrix in the pixel array. According to an embodiment, one pixel group PXG may include the pixels PX (e.g., first to eighth pixels PX1 to PX8) arranged in the form of a 2×4 matrix, as illustrated in FIGS. 3A and 3B. However, the number of pixels PX included in one pixel group PXG is not limited thereto, and according to various embodiments may include various numbers of pixels PX.

The pixel group PXG may include the plurality of pixels including the photoelectric conversion devices PD formed in the semiconductor substrate 101 and various lines provided in the semiconductor substrate 101 or on the semiconductor substrate 101, an isolation layer 110, a color filter CF, and a micro-lens LS.

The semiconductor substrate 101 may be a silicon substrate, a germanium substrate, a silicon-germanium substrate, a group II-VI compound semiconductor substrate, a group III-V compound semiconductor substrate, or a silicon on insulator (SOI) substrate. In some embodiments, the semiconductor substrate 101 may include impurities in the first conductive type. Accordingly, the semiconductor substrate 101 may have the first conductive type. The impurities in the first conductive type may be group III elements. For example, in some embodiments, the impurities in the first conductive type may include P-type impurities, such as aluminum (Al), boron (B), indium (In), and/or gallium (Ga).

The semiconductor substrate 101 may have a front surface 101f and a rear surface 101r facing each other. Light may be incident to the rear surface 101r of the semiconductor substrate 101.

The lines in the pixel PX, which are components serving as conductors to transmit charges, may include an active area 120 doped with impurities, a polysilicon pattern 130 doped with impurities, a connection line 140, a signal line ML, and/or a contact part CT.

According to an embodiment, the polysilicon pattern 130 and the active areas 120 may constitute a specific transistor. The polysilicon pattern 130 may be used as a gate, and the two active areas 120, which are disposed while interposing the polysilicon pattern 130 between the two active areas 120, may be used as a source and a drain, respectively. In some embodiments, the active area 120 may be used as the floating diffusion area FD or the ground area GND.

The polysilicon pattern 130 and the active areas 120 will be described in more detail below.

The active area 120, which is a portion of the semiconductor substrate 101, is an area doped with impurities in the first conductive type or a second conductive type. The active area 120 may be formed to have a specific depth from the substrate surface of the semiconductor substrate 101. The active area 120 may be used as a source or drain of transistors and may also be used as the ground area GND. The active area 120 may achieve various electrical junctions through a junction with metal or a junction with the active area 120 doped with impurities in different conductive types. According to an embodiment, the first to eighth floating diffusion areas FD1, FD2, . . . , and FD8, the source and drain of the source follower transistor SF, the source and drain of the selection transistor SEL, the source and drain of the first to third reset transistors RX1, RX2, and RX3, and the ground areas GND may be formed of the active area 120.

The polysilicon pattern 130 is doped with impurities of the first conductive type or the second conductive type. According to an embodiment, the polysilicon pattern 130 may be used as a gate of a transistor. According to an embodiment, the first to eighth transfer gates TG1, TG2, . . . , and TG8 of the first to eighth transfer transistors TX1, TX2, . . . , and TG8, the source follower gate SFG of the source follower transistor SF, the selection gate SG of the selection transistor SEL, and the first to second reset gates RG1, RX2, and RG3 of the first to third reset transistors RX1, RX2, and RX3 may be formed of the polysilicon pattern 130. In some embodiments, at least one of the polysilicon patterns 130 may be used as an electrode to apply a ground voltage to the ground areas GND.

The connection line 140 connects the polysilicon pattern 130 and a portion of the active area 120. The details thereof will be described below.

The signal line ML is a line provided on the semiconductor substrate 101 to transmit various electrical signals of the image sensor (best seen in FIG. 4). The signal line ML may be provided on at least one interlayer insulating layer stacked on the semiconductor substrate 101.

At least one interlayer insulating layer may be provided. In the drawings, for convenience of explanation, it is illustrated that the interlayer insulating layer includes two layers which are a first interlayer insulating layer 153 and a second interlayer insulating layer 155. However, the number of interlayer insulating layers is not limited thereto. For example, according to an embodiment, at least two interlayer insulating layers may be further provided.

Signal lines, for example, a first signal line M1 and a second signal line M2, may be provided on the first interlayer insulating layer 153 and the second interlayer insulating layer 155, respectively. The first and second interlayer insulating layers 153 and 155 may be connected to each other through the contact part CT formed through the interlayer insulating layer.

According to an embodiment, the contact part CT connects the polysilicon pattern 130 and the active area 120 provided under the first interlayer insulating layer 153 to the signal line ML provided over the first interlayer insulating layer 153. In other words, the contact part CT connects the polysilicon pattern 130 and/or the active area 120 to the first signal line M1 through the first interlayer insulating layer 153. The second signal line M2 on the second interlayer insulating layer 155 may be connected to the first signal line M1 on the first interlayer insulating layer 153 through the contact part CT formed through the second interlayer insulating layer 155 (see.

The pixels PX may be connected to each other or to an external component through signal lines ML provided in multiple layers.

According to an embodiment, the transistors in the pixel group PXG may be n-MOS type transistors, and the source and the drain of each transistor, which are the active areas 120, may be areas doped with impurities (which is an N-type impurity) in the second conductive type. However, in some embodiments, the transistors may be p-MOS type transistors. Accordingly, the positions of the source and the drain of each transistor may be different than that illustrated in FIGS. 3A-4.

According to an embodiment, one pixel group PXG may include first to eighth pixels PX1, PX2, . . . , and PX8 arranged in the form of a 2×4, as illustrated in drawings. Each of the first to eighth pixels PX1, PX2, . . . , and PX8 includes a photoelectric conversion device, a floating diffusion area, and a transfer transistor. In other words, the first pixel PX1 includes the photoelectric conversion device PD, the first floating diffusion area FD1, and the first transfer transistor TX1, and the second pixel PX2 includes the photoelectric conversion device PD, the second floating diffusion area FD2, and the second transfer transistor TX2, the third pixel PX3 includes a photoelectric conversion device PD, the third floating diffusion area FD3, and the third transfer transistor TX3, and a fourth pixel PX4 includes a photoelectric conversion device PD, the fourth floating diffusion area FD4, and the fourth transfer transistor TX4. Each of the fifth to eighth pixels includes a corresponding photoelectric conversion device, a corresponding floating diffusion area, and a corresponding transfer transistor.

In some embodiments, one pixel group PXG may further include the first reset transistor RX1, the second reset transistor RX2, the source follower transistor SF, and the selection transistor SEL.

For example, the first reset transistor RX1, the second reset transistor RX2, the third reset transistor RX3, the source follower transistor SF, and/or the selection transistor SEL may be included in any one of the first to eighth pixels PX1, PX2, . . . , and PX8, respectively. For example, the first reset transistor RX1 may be provided in the sixth pixel PX6, the second reset transistor RX2 may be provided in the second pixel PX2, the third reset transistor RX3 may be provided in the fourth pixel PX4, and the source follower transistor SF may be provided in the third pixel PX3 and the fifth pixel PX5. The selection transistor SEL may be provided in the eighth pixel PX8. In some embodiments, at least one ground area GND may be provided in at least one pixel groups PXG. For example, the ground area GND may be provided to the first pixel PX1 and the seventh pixel PX7. However, arrangement of lines including transistors in the pixel group PXG is not limited thereto and, in various embodiments, may be formed differently.

The photoelectric conversion device PD is provided for each pixel PX and may be interposed between the front surface 101f and the rear surface 101r of the semiconductor substrate 101. The photoelectric conversion device PD may be a doped area including impurities in the second conductive type. According to an embodiment, the photoelectric conversion device PD may include a group V element, and the group V element may be an impurity in a second conductive type. The impurity in the second conductive type may be opposite to the impurities in the first conductive type, in terms of a conductive type. The impurities in the second conductive type may include n-type impurities such as phosphorus, arsenic, bismuth, and/or antimony.

The ground area GND may be included in the active area 120 for each pixel. The ground area GND may have the first conductive type. According to some embodiments, the ground area GND may have the first conductive type at an impurity concentration higher than an impurity concentration of the semiconductor substrate 101. For example, the ground area GND may be an impurity area formed by ion-implanting p-type impurities (p++) at a higher concentration into the semiconductor substrate 101 in the p type.

The first to eighth floating diffusion areas FD1, FD2, . . . , and FD8 may be included in the active area 120 in the semiconductor substrate 101. The first to eighth floating diffusion areas FD1, FD2, . . . , and FD8 may be spaced apart from the photoelectric conversion device PD and the ground area GND. The first to eighth floating diffusion areas FD1, FD2, . . . , and FD8 may have the second conductive type, and for example, may be impurity areas having the second conductive type formed by ion-implanting n-type impurities into the semiconductor substrate 101 in the p type.

According to some embodiments, the first to eighth floating diffusion areas FD1 to FD8 may have the second conductive type with an impurity concentration higher than that of the photoelectric conversion device PD. For example, the floating diffusion area FD may be formed by ion-implanting high-concentration n-type impurities (n+) into the p-type semiconductor substrate 101. A channel area may be formed between the photoelectric conversion device PD and the floating diffusion area FD.

The first to eighth transfer transistors TX1, TX2, . . . , and TX8 may include the first to eighth transfer gates TG1, TG2, . . . , and TG8, which form a transfer channel between the photoelectric conversion devices PD and the first to eighth floating diffusion areas FD1, FD2, . . . , and FD8, a gate insulating layer 151 to insulate the semiconductor substrate 101 from the first to eighth transfer gates TG1, TG2, . . . , and TG8, and a gate spacer provided on a side surface of each of the first to eighth transfer gates TG1, TG2, . . . , and TG8. In some embodiments, the first to eighth transfer gates TG1, TG2, . . . , and TG8 may have a buried gate structure. Each of the first to eighth transfer gates TG1, TG2, . . . , and TG8 may have a pair of electrodes spaced apart from each other. However, embodiments are not limited thereto. For example, each of the first to eighth transfer gates TG1, TG2, . . . , and TG8 may be provided in one electrode.

An interlayer insulating layer may be provided on the entire surface on which the first to eighth transfer gates TG1, TG2, . . . , and TG8 are formed. According to an embodiment, the interlayer insulating layer may be provided in the form a single layer or a multilayer, and the multilayer, for example, may include the first and second interlayer insulating layers 153 and 155. The first and second interlayer insulating layers 153 and 155 may include at least one of silicon oxide, silicon nitride, silicon oxynitride, and a material having a dielectric constant (lowk) lower than that of the silicon oxide, but embodiments are not limited thereto. For example, the first interlayer insulating layer 153 may include a material such as an undoped silicate glass (USG), for example, a tetraethyl orthosilicate (TEOS).

The isolation layer 110 may be provided between pixels PX adjacent to each other to partition the pixels PX. In particular, the pixels PX adjacent to each other may be separated from each other by the isolation layer 110. The isolation layer 110 may be provided along the circumference of the photoelectric conversion devices PD, for example, when viewed in a plan view.

The isolation layer 110 may include a pixel isolation layer 111 surrounding the photoelectric conversion device PD when viewed in a plan view, and/or a shallow isolation layer 113 provided with a depth shallower than the pixel isolation layer 111.

The pixel isolation layer 111 may be formed in the semiconductor substrate 101 to surround each of the pixels PX. The pixel isolation layer 111 may be provided, for example, in the form in which an insulating material is buried in a deep trench formed through the semiconductor substrate 101. In other words, the pixel isolation layer 111 may be provided in the form of a deep trench isolation (DTI). In some embodiments, at least some of the deep trenches may be formed through the semiconductor substrate 101. For example, at least some of the deep trench may be formed through from the rear surface 101r to the front surface 101f of the semiconductor substrate 101 or from the front surface 101f to the rear surface 101r of the semiconductor substrate 101.

According to an embodiment, the pixel isolation layer 111 may include a conductive isolation layer 110b formed by filling a conductive material in the deep trench, and an insulating liner 110a provided between the semiconductor substrate 101 and the conductive isolation layer 110b. The conductive isolation layer 110b may include a crystalline semiconductor material, for example, polysilicon doped with an impurity. The conductive isolation layer 110b is spaced apart from the semiconductor substrate 101 through the insulating liner 110a. Accordingly, during an image sensor operation, the conductive isolation layer 110b may be electrically isolated from the semiconductor substrate 101.

The shallow isolation layer 113 may be provided in a shallow trench recessed by a specific depth from the front surface 101f when viewed in a cross-sectional view. Unlike the deep trench, the shallow trench is recessed only by the specific depth from the front surface 101f of the semiconductor substrate 101 without passing through the semiconductor substrate 101. According to an embodiment, the shallow isolation layer 113 may be formed in multiple layers. The shallow isolation layer 113 may also include at least one of silicon oxide, silicon nitride, silicon oxynitride, or a combination thereof, but embodiments are not limited thereto.

According to an embodiment, the shallow isolation layer 113 may be provided along the circumference of one pixel PX such that the one pixel PX is spaced apart from a pixel PX adjacent to the one pixel PX, but embodiments are not limited thereto. For example, in some embodiments, the shallow isolation layer 113 may also be provided for electrical isolation between two adjacent components which are provided within one pixel PX. For example, in some embodiments, a shallow isolation layer 113 may be provided between the floating diffusion area and the ground area GND adjacent to each other in one pixel PX to electrically isolate the floating diffusion area from the ground area GND. According to an embodiment, some drawings illustrate examples which the isolation layer 110 includes both the pixel isolation layer 111 and the shallow isolation layer 113, but these drawings are provided only for convenience of explanation. For example, in some embodiments, the isolation layer 110 may include the shallow isolation layer 113 without the pixel isolation layer 111. In some embodiments, the shallow isolation layer 113 may not be provided at a corner portion of each pixel PX in which the floating diffusion area is provided.

A rear insulating layer 157 may be provided on the rear surface 101r of the semiconductor substrate 101. The rear insulating layer 157 may cover the rear surface 101r of the semiconductor substrate 101, and, in some embodiments, may be provided in multiple layers. The rear insulating layer 157 may include, for example, a silicon-based insulating material such as silicon oxide, silicon nitride, and/or silicon oxynitride.

The color filter CF may be provided on the rear insulating layer 157. The color filter CF may be disposed on the rear surface 101r of the semiconductor substrate 101 for each pixel. For example, the color filters CF may be provided at positions corresponding to the photoelectric conversion devices PD, respectively. Each of the color filters CF may include any one of a red filter, a blue filter, or a green filter, but embodiments are not limited thereto. For example, the color filters CF may include different color filters. The color filters CF may constitute color filter arrays.

The micro-lens LS may be disposed on the rear surface 101r of the semiconductor substrate 101. For example, the micro-lens LS may be disposed on the color filter CF. The micro-lens LS may include a lens pattern and a planarization portion. The planarization portion of the micro-lens LS may be provided on the color filters CF. The lens pattern may be provided on the planarization portion. The lens pattern is integrally formed with the planarization portion and may be connected to the planarization portion without an interface. The lens pattern may include the same material as the planarization portion. For another example, the planarization portion may be omitted, and the lens pattern may be disposed on the color filters CF.

The lens pattern may be hemispherical. The lens pattern may condense incident light. The lens pattern may be provided at a position corresponding to the photoelectric conversion devices PD of the semiconductor substrate 101. The micro-lens LS may be transparent and transmit light. The micro-lens LS may include an organic material such as a polymer. For example, the micro-lens LS may include a photoresist material or a thermosetting resin.

When the lines are connected to each other on the semiconductor substrate 101 in the image sensor according to an embodiment, the lines may be connected with each other using the connection lines.

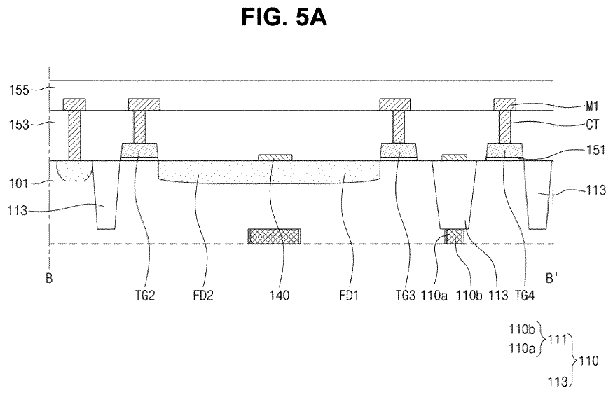

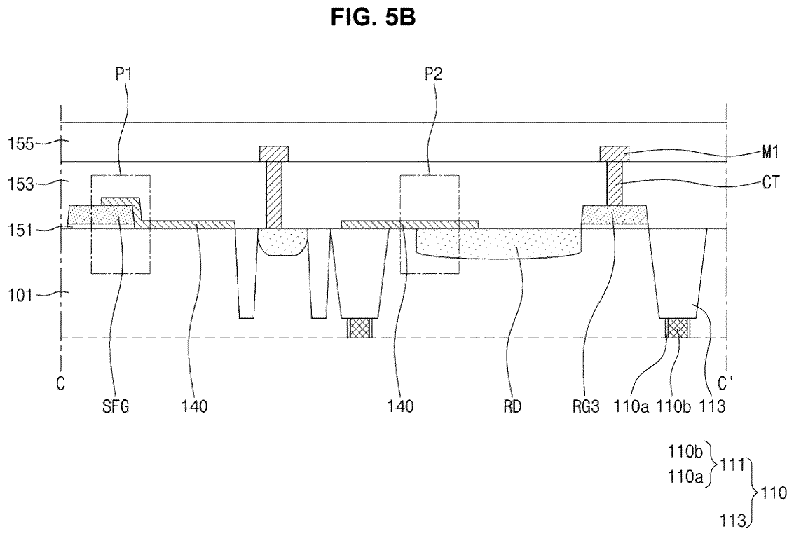

FIGS. 5A and 5B are cross-sectional views taken along the lines B-B′ and C-C′ of FIG. 3A, respectively, in which a part of an image device including a connection line is illustrated. It is noted that some of the components among the components in FIG. 3A are omitted in FIGS. 5A and 5B for clarity of description, and a form in which the image sensor of FIG. 4 is inverted is illustrated in FIGS. 5A and 5B for convenience of explanation.

Referring to FIGS. 3A, 3B, 4, 5A, and 5B, according to an embodiment, some of the gate, source, drain of each transistor, a ground area, and a floating diffusion area in one pixel group PXG are connected to each other through the connection lines 140 and others of the gate, source, drain of each transistor, a ground area, and a floating diffusion area in one pixel group PXG is connected by the signal line ML.

The connection line 140 may include various conductive materials. For example, the connection line 140 may include a metal such as aluminum, copper, tungsten, titanium, tantalum, or an alloy thereof. However, the material of the connection line 140 is not limited thereto. For example, the material of the connection line 140 may include other materials having conductivity, for example, various metals other than the metal, the alloy thereof, or doped inorganic materials may be used.

The connection lines 140 connect the source follower gate SFG to at least one of the first to eighth floating diffusion areas FD1, FD2, . . . , and FD8. In this case, the connection line 140, the source follower gate SFG, and the floating diffusion area correspond to floating diffusion nodes.

One end of the connection line 140 may make contact with the source follower gate SFG without an additional contact part CT or an additional signal line M1 (see, e.g., FIG. 5B), and an opposite end of the connection line 140 may make contact with at least one of the first to eighth floating diffusion areas FD1, FD2, . . . , and FD8. In addition embodiment, a portion of the connection line 140 may make contact with and connected to the drain RD of the third reset transistor RX3.

The connection line 140 may be integrally formed without being separated into segments. In other words, as shown in FIGS. 3A and 3B, there are no breaks in the connection line 140 and the connection line 140 may extend from the source follower gate SFG to at least one of the first to eighth floating diffusion areas FD1, FD2, . . . , or FD8 without being separated into segment parts. According to an embodiment, the connection line 140 may connect all of the source follower gate SFG and the first to eighth floating diffusion areas FD1, FD2, . . . , and FD8. Even in this case, the connection line 140 may be integrally provided without being separated.

According to an embodiment, the first to fourth floating diffusion areas FD1, FD2, . . . , and FD4 of the first to fourth pixels PX1, PX2, . . . , and PX4 may be disposed to be adjacent to each other. For example, the first to fourth floating diffusion areas FD1, FD2, . . . , and FD4 may be disposed at corners, which face each other, of the first to fourth pixels PX1 to PX4. Similarly, the fifth to eighth floating diffusion areas FD5, FD6, . . . , and FD8 of the fifth to eighth pixels PX5, PX6, . . . , and PX8 may be disposed adjacent to each other. For example, the fifth to eighth floating diffusion areas FD5, FD6, . . . , and FD8 may be disposed at corners facing each other of the fifth to eighth pixels PX5 to PX8.

The first to fourth floating diffusion areas FD1, FD2, . . . , and FD4 and the fifth to eighth floating diffusion areas FD5, FD6, . . . , and the FD8 are disposed at adjacent positions. Accordingly, first to fourth floating diffusion areas FD1, FD2, . . . , and FD4 and the fifth to eighth floating diffusion areas FD5, FD6, . . . , and the FD8 may be easily connected to each other using the connection line 140. However, the arrangement positions of the first to eighth floating diffusion areas FD1, FD2, . . . , and FD8 are not limited thereto, and in some embodiments may be arranged in various forms within a connection limit of the connection line 140. Even when the first to eighth floating diffusion areas FD1, FD2, . . . , and FD8 are disposed at positions which are not adjacent to each other in the pixel PX, the connection may be made through the connection line 140.

According to an embodiment, the first to fourth floating diffusion areas FD1, FD2, . . . , and FD4 and the fifth to eighth floating diffusion areas FD5, FD6, and . . . , and FD8 may be connected to each other at edge sides facing each other and may be provided integrally without being separated from each other.

One end portion of the connection line 140 may be connected to the source follower gate SFG by making contact with the top surface of the source follower gate SFG. An opposite end portion of the connection line 140 may be connected to the first to eighth floating diffusion areas FD1, FD2, . . . , and FD8 by making contact with top surfaces of at least some of the first to fourth floating diffusion areas FD1, FD2, . . . , and FD4 and the fifth to eighth floating diffusion areas FD5, FD6, . . . , and FD8. Accordingly, one end portion of the connection line 140 may be overlapped with the source follower gate SFG, and the opposite end portion of the connection line 140 may be overlapped with at least some of the first to eighth floating diffusion areas FD1, FD2, . . . , and FD8, when viewed in a plan view.

According to an embodiment, the opposite end portion of the connection line 140 may be connected with the central portion of each of the first to fourth floating diffusion areas FD1, FD2, . . . , and FD4 and each of the fifth to eighth floating diffusion areas FD5, FD6, . . . , and FD8 as illustrated in drawings.

However, the form of connecting the connection line 140 with the first to eighth floating diffusion areas FD1, FD2, . . . , and FD8 is not limited thereto. For example, each of the first to eighth floating diffusion areas FD1, FD2, . . . , and FD8 may be provided for corresponding pixels, and may be provided in the form of an island, such that the first to eighth floating diffusion areas FD1, FD2, . . . , and FD8 are spaced apart from each other and separated from each other. In this case, the connection line 140 may make contact with each of the floating diffusion areas having the form of a separated island. For example, the connection line 140 may include branch portions extending in directions of the first to eighth floating diffusion areas FD1, FD2, . . . , and FD8, respectively, and the branch portions may extend to the top surfaces of the first to eighth floating diffusion areas FD1, FD2, . . . , and FD8 and may make contact with the top surfaces of the first to eighth floating diffusion areas FD1, FD2, . . . , and FD8.

When the connection line 140 is connected from the source follower gate SFG to the first to eighth floating diffusion areas FD1, FD2, . . . , and FD8, at least a portion of the connection line 140 may be disposed along the edge of the pixel PX. The edge of the pixel PX is an area in which other gates or the active areas 120 are not provided. Even when the connection line 140 is provided, there is an advantage in which spatial constraints are not caused in the arrangement of other components. The edge of each pixel PX is a portion in which the isolation layer 110 is provided. Since the connection line 140 may be provided at the edge of each pixel, at least a portion of the connection line 140 may be overlapped with the isolation layer 110, when viewed in a plan view. In an embodiment, at least a portion of the connection line 140 may extend in the extending direction of the isolation layer 110.

According to an embodiment, the connection line 140 may be provided on the top surface of the isolation layer 110 (see, e.g., FIGS. 5A and 5B). The connection line 140 may be provided on the shallow isolation layer 113 particularly at the edge of the pixel PX in which the pixel isolation layer 111 and the shallow isolation layer 113 are stacked. The width of the shallow isolation layer 113 stacked on the pixel isolation layer 111 may be formed to be wider than that of another shallow isolation layers 113 in the pixel PX (see, e.g., FIG. 5A). The connection line 140 may be disposed on the shallow isolation layer 113 having a wider width, thereby minimizing the occurrence of parasitic capacitance which is caused between the connection line 140 and other lines.

According to an embodiment, separate contact parts CT and signal lines ML connecting the source follower gate SFG and the floating diffusion area may be omitted by providing the connection line 140. The omission of the separate contact parts CT and the separate signal lines ML may not only prevent parasitic capacitance due to the separate contact parts CT and the signal lines ML, but also allow other lines to be installed in the place where the original contact parts CT and the signal lines ML were located. In other words, the omission of the separate contact parts CT and the separate signal lines ML may reduce the layer for the signal line ML and increase the degree of freedom in space when the lines of the semiconductor device are formed.

According to an embodiment, the connection line may connect lines other than the signal line, in addition to the connection between the source follower gate SFG and the first to eighth floating diffusion areas FD1, FD2, . . . , and FD8. For example, the connection line may connect ground areas of pixels adjacent to each other. When connecting the ground areas of the pixels adjacent to each other, the connection line may be provided separately from the connection line for connecting the gate of the source follower transistor to the first to eighth floating diffusion areas FD1, FD2, . . . , and FD8.

The first interlayer insulating layer 153 may be provided on the semiconductor substrate 101 having the transistors, the active areas 120, the ground areas GND, and the connection line 140 in the pixel group PXG.

First signal lines M1 may be provided on the first interlayer insulating layer 153. A second interlayer insulating layer 155 and a second signal line M2 may be provided on the first interlayer insulating layer 153. The contact parts CT formed through the first interlayer insulating layer 153 and the second interlayer insulating layer 155 may be provided between the first interlayer insulating layer 153 and the first signal lines M1 and between the second interlayer insulating layer 155 and the second signal lines M2.

The contact parts CT may be provided on gates, sources and drains of some transistors to connect the gates, sources and drains of some transistors to the first and/or second signal lines M1 and M2. Specifically, the first and/or second signal lines M1 and M2 may be connected to the selection gate SG through the contact part CT provided on the selection gate SG. The first and/or second signal lines M1 and M2 may be connected to upper portions of the first to eighth transfer gates TG1, TG2, . . . , and TG8 through the contact parts CT provided on the first to eighth transfer gates TG1, TG2, . . . ,and TG8, respectively. The first and/or second signal lines M1 and M2 may be connected to the first to third reset gates RG1 to RG3, respectively, through the contact parts CT provided on the first to third reset gates RG1 to RG3.

The source of the source follower transistor SF and the drain of the selection transistor SEL may be connected to each other through the contact parts CT, which are provided on the source of the source follower transistor SF and the drain of the selection transistor SEL, and the first signal line MI connecting the two contact parts CT. The source of the selection transistor SEL may be connected to the first and/or second signal lines M1 and M2 through the contact part CT to output the pixel signal V_{OUT} to the first and/or second signal lines M1 and M2. The drain of the third reset transistor RX3 may be connected to the connection line 140. The source/drain of the third reset transistor and the second reset transistor RX2 may be connected to each other through the contact parts CT provided on the top surface of the third reset transistor and the second reset transistor RX2 and the first signal line M1 connecting the two contact parts CT. The drain of the source follower transistor SF and the source of the first reset transistor RX1 may be connected to the first and/or second signal lines M1 and M2 through the contact parts CT, such that a power supply voltage VDD is applied through the first and/or second signal lines M1 and M2.

According to an embodiment, the connection line may be formed on the semiconductor substrate, but in some embodiments, a protective layer may be further provided at a lower portion and an upper portion of the connection line.

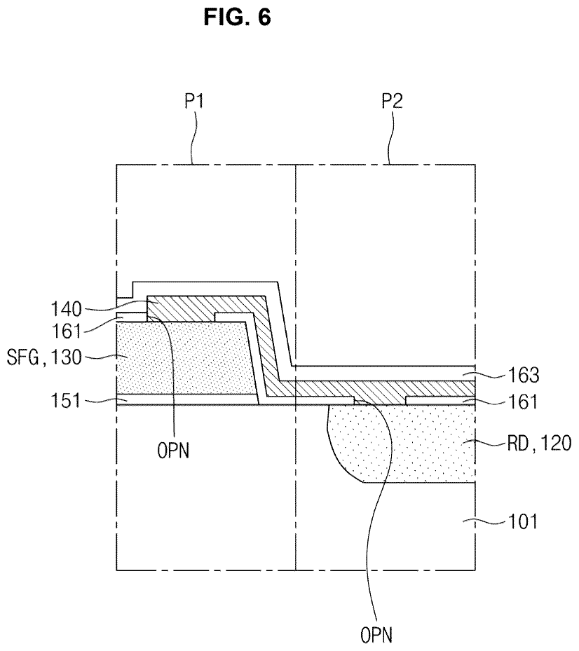

FIG. 6 is cross-sectional views corresponding to parts P1 and P2 of FIG. 5B, and illustrates that first and second protective layers are provided at lower and upper sides of the connection line, respectively, according to some embodiments.

Referring to FIG. 6, a first protective layer 161 may be provided on the semiconductor substrate 101 at the source follower gate SFG that includes the polysilicon pattern 130. The first protective layer 161 is provided on the semiconductor substrate 101 at the drain RD of the third reset transistor RX3 included in the active area 120.

The first protective layer 161 may be formed of an insulating material. The first protective layer 161 prevents the metal constituting the connection line 140 from penetrating into the semiconductor substrate 101, when the connection line 140 is formed in a subsequent process and is formed of metal. The first protective layer 161 may be formed of silicon oxide, silicon nitride, and/or silicon oxynitride.

The first protective layer 161 may include an opening OPN to expose a portion of a top surface of the source follower gate SFG and a top surface of the drain RD of the third reset transistor RX3. For example, in some embodiments, an opening OPN may be formed on the top surface of the source follower gate SFG and an opening OPN may be formed on the top surface of the drain RD. The opening OPN may be formed by forming a photoresist layer on the first protective layer 161, performing a exposure process using a mask, and performing a developing process for the exposed photoresist layer, and then etching a lower first protective layer 161 using the separated photoresist layer as a mask. The connection line 140 is provided on the first protective layer 161 having the opening OPN formed therein. The connection line 140 may be formed by forming a line layer using a conductive material and then patterning the line layer through a photolithography process. The above-described conductive material may be used as the conductive material for forming the connection line 140. The connection line 140 electrically connects the source follower gate SFG and the drain RD of the third reset transistor RX3 by bringing the source follower gate SFG into contact with the top surface of the drain RD of the third reset transistor RX3, respectively, by contacting the source follower gate SFG and the drain RD through the opening OPN which serves as a contact hole. For example, the connection line 140 electrically connects the source follower gate SFG and the drain RD of the third reset transistor RX3 by bringing the source follower gate SFG into contact with the top surface of the drain RD of the third reset transistor RX3, respectively, by contacting the source follower gate SFG and the drain RD through the opening OPN. A second protective layer 163 may be provided on the semiconductor substrate 101 having the connection line 140. In other words, the second protective layer 163 may cover the connection line 140 on the semiconductor substrate 101.

In an embodiment, the first to eighth floating diffusion areas FD1, FD2, . . . , and FD8 are included in the active area 120, and are connected to the connection line 140 in a manner the same as a manner in which the connection line 140 is connected to the drain RD of the third reset transistor RX3. Accordingly, the details thereof will be omitted for conciseness.

Each of the first protective layer 161 and/or the second protective layer 163 may be selected from various insulating materials having a lower dielectric constant. In some embodiments, the first protective layer 161 and/or the second protective layer 163 may be selected from a material for forming the semiconductor substrate 101, for example, a material having an etch selectivity higher than an etch selectivity of silicon or silicon oxide. The first protective layer 161 and/or the second protective layer 163 may include, for example, a silicon-based insulating material (e.g., Si₃N₄, SiCOH, SiO₂, SiCN, or SiOCN), and/or may include a high dielectric metal oxide (e.g., hafOx), zirconium oxide (ZrO₂), titanium oxide (TiO₂), aluminum oxide (Al₂O₃; alumina), etc.

As described above, the image sensor according to an embodiment employs connection lines to electrically and mutually connect specific components to each other. Unlike the related art technology which employs only contact parts and signal lines, when the structure in which a connection line is used as in the various embodiments described above, parasitic capacitance between adjacent components is minimized. Accordingly, the conversion gain of pixels is maximized and random noise is minimized due to the decrease in parasitic capacitance.

In some embodiments, the contact parts and signal lines for connecting the gate of the original source follower transistor and the floating diffusion area are omitted, thereby freeing up a space for placing different lines in positions that would otherwise be occupied by the contact parts and the signal lines. According to an embodiment, an extra space for placing different lines is provided by using the connection line, thereby reducing the signal line layer and increasing the degree of freedom in space when lines are formed in the semiconductor device. A signal line disposed on another interlayer insulating layer may be moved and formed in the extra space.

According to an embodiment, the connection line integrally connecting the first to eighth floating diffusion areas and the drain of the third reset transistor has been described by way of example, but embodiments are not limited thereto. For example, in some embodiments, the first to eighth floating diffusion areas may be connected by using separate connection lines different from each other. In some embodiments, when the connection line only partially connects some of the first to eighth floating diffusion areas, the floating diffusion areas, which are not connected, may be connected to the signal line through the contact part.

According to an embodiment, at least a part of the connection line may be overlapped with the isolation layer when viewed in a plan view and extend in the extending direction of the isolation layer, and may be embedded in the semiconductor substrate.

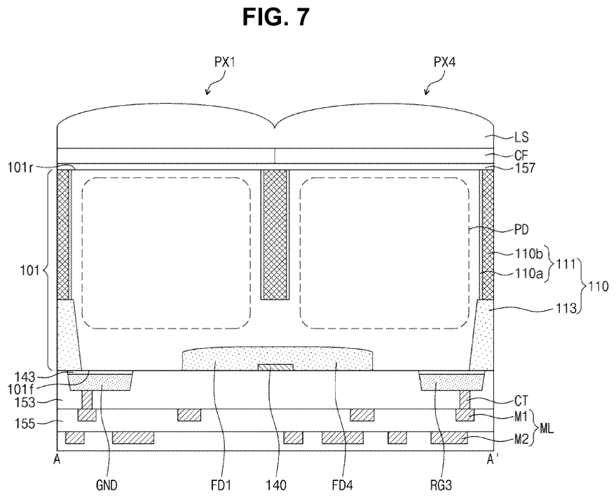

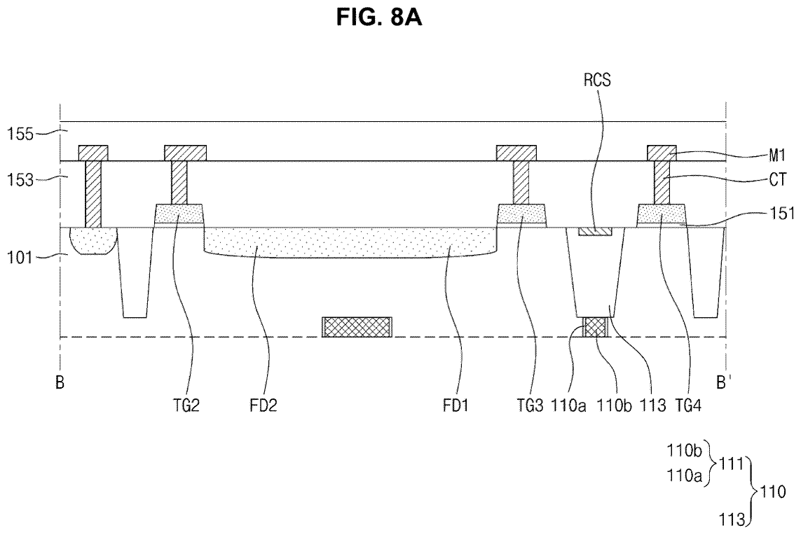

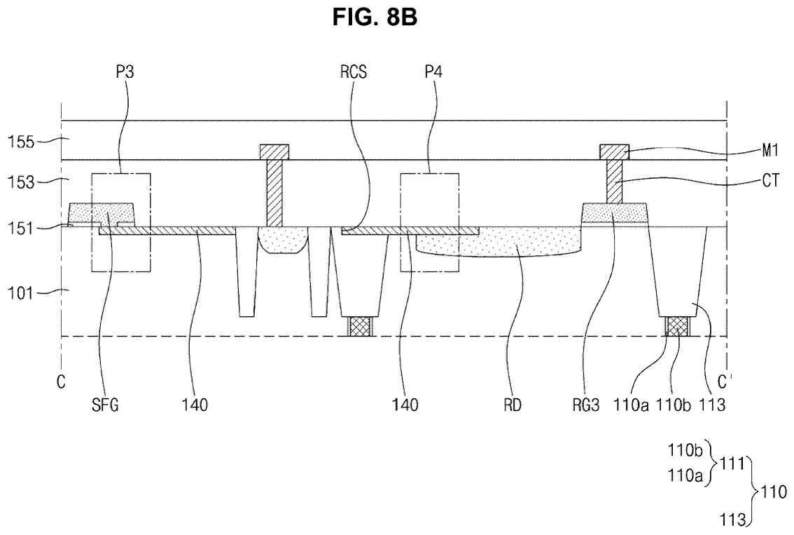

FIG. 7 is a cross-sectional view corresponding to line A-A′ of FIG. 3A, according to some embodiments, and FIG. 8A and FIG. 8B are cross-sectional views corresponding to line B-B′ and line C-C′ of FIG. 3A, respectively, in which some of the components are omitted for convenience of explanation.

Referring to FIGS. 3A, 3B, 7, 8A, and 8B, according to an embodiment, the connection line 140 may be buried in the semiconductor substrate 101 or the active area 120. In particular, in an embodiment, at least a portion of the connection line 140 may be buried in the shallow isolation layer 113. In an embodiment, at least a portion of the connection line 140 may be buried in the semiconductor substrate 101 (see, e.g., FIG. 8B). In detail, the connection line 140 be provided in the semiconductor substrate 101, an active area 120 doped with impurities, and/or a recess part RCS recessed from the top surface of the shallow isolation layer 113, and the connection line 140 may be provided in the recessed portion RCS.

Referring to FIGS. 3A, 3B, and 8A, one end portion of the connection line 140 may be overlapped with the active area 120 when viewed in a plan view, and may have a shape buried in the active area 120 when viewed in a cross-sectional view. In other words, when viewed in a cross-sectional view, the active area 120 has the recess part RCS, and the connection line 140 is disposed in the recess part RCS. The active area 120 and the connection line 140 make contact with each other to be electrically connected to each other. In this case, a top surface of the connection line 140 may have be co-planar with a top surface of the active area 120.

In an embodiment, the connection line 140 may be buried in the isolation layer 110, particularly, in the shallow isolation layer 113. The shallow isolation layer 113 has the recess part RCS, and the connection line 140 is disposed in the recess part RCS. In this case, the top surface of the connection line 140 may be coplanar with the top surface of the shallow isolation layer 113. The width of the shallow isolation layer 113, which is provided on the pixel isolation layer 111, among the shallow isolation layers 113 in the pixel PX is formed to be wider than the width of the remaining shallow isolation layers 113 in the pixel PX. The connection line 140 may be disposed in the shallow isolation layer 113 on the pixel isolation layer 111 having a wider width, thereby increasing the gap between the connection lines 140 and different lines to minimize parasitic capacitance which is caused by the different lines.

Referring to FIGS. 3A, 3B, and 8B, an opposite end portion of the connection line 140 may be overlapped with the source follower gate SFG when viewed in a plan view, and may have a shape buried in the semiconductor substrate 101 when viewed in a cross-sectional view. In this case, the top surface of the connection line 140 may be matched with (i.e., coplanar with) the top surface of the semiconductor substrate 101.

The gate insulating layer 151 may be interposed between the polysilicon pattern 130 forming the source follower gate SFG and the top surface of the connection line 140. An opening exposing the top surface of the connection line 140 may be formed in the gate insulating layer 151, and the source follower gate SFG and the top surface of the connection line 140 make contact with each other through the opening. The polysilicon pattern 130 forming the source follower gate SFG and the connection line 140 may be electrically connected to each other through a contact.

In an embodiment, the connection line 140 may be embedded in and extended in the shallow isolation layer 113, the semiconductor substrate 101, and the active area 120. The shallow isolation layer 113, the semiconductor substrate 101, and the active area 120 have the recess part RCS, and the connection line 140 may be disposed in the recess part RCS. In this case, the top surface of the connection line 140 may be matched with (i.e., coplanar with) top surfaces of the shallow isolation layer 113, the semiconductor substrate 101, and the active area 120.

According to an embodiment, although the above-described diagrams illustrate that the connection line 140 is formed on the semiconductor substrate 101, a protective layer may be further provided at a lower portion and an upper portion of the connection line 140.

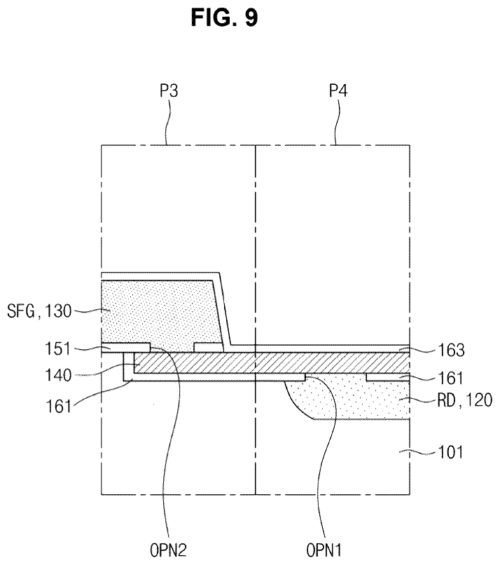

FIG. 9 is a cross-sectional view corresponding to parts P3 and P4 of FIG. 8B, and illustrates that first and second protective layers are provided at a lower portion and an upper portion of the connection line, respectively, according to some embodiments.

Referring to FIG. 9, a first protective layer 161 may be provided between the semiconductor substrate 101, the active area 120, and the connection line 140.

The first protective layer 161 may be formed of an insulating material. The first protective layer 161 prevents the metal constituting the connection line 140 from penetrating into the semiconductor substrate 101, when the connection line 140 is formed thereafter and is formed of metal. The first protective layer 161 may be formed of silicon oxide, silicon nitride, and/or silicon oxynitride.

A first opening OPN1 to expose a portion of the top surface of the active area 120 to the outside may be provided in the first protective layer 161. The connection line 140 may be provided on the first protective layer 161 having the first opening OPN1 formed therein. The connection line 140 may be formed by forming the line layer with a conductive material and then patterning the line layer through the photolithography process. As the conductive material forming the connection line 140, the above-described conductive material may be used. The connection line 140 makes contact with the top surface of the active area 120 through the first opening OPN1, such that the connection line 140 and the active area 120 are electrically connected to each other. For example, the connection line 140 is electrically connected with the drain RD of the third reset transistor RX3. The gate insulating layer 151 is interposed between the connection line 140 and the polysilicon pattern 130. The gate insulating layer 151 has a second opening OPN2 to expose the top surface of the connection line 140. The polysilicon pattern 130 makes contact with the top surface of the connection line 140 through the second opening OPN2, respectively, such that the polysilicon pattern 130 and the connection line 140 are electrically connected to each other. The second protective layer 163 may be provided on the connection line 140 and the polysilicon pattern 130.

As described above, the connection line may be buried and provided in the isolation layer, and in particular, may be buried in the shallow isolation layer at the edge of the pixel in which the pixel isolation layer and the shallow isolation layer are stacked. The shallow isolation layer, which is provided on the pixel isolation layer, among the shallow isolation layers in the pixel has a wider width than remaining shallow isolation layers in the pixel. The connection line may be buried in the shallow isolation layer on the wider pixel isolation layer, thereby increasing the gap between the connection lines and different lines to minimize parasitic capacitance which is caused between the different lines.

According to an embodiment, the connection relationship between the polysilicon pattern and the active area may be provided in a form different from which of the above-described embodiments.

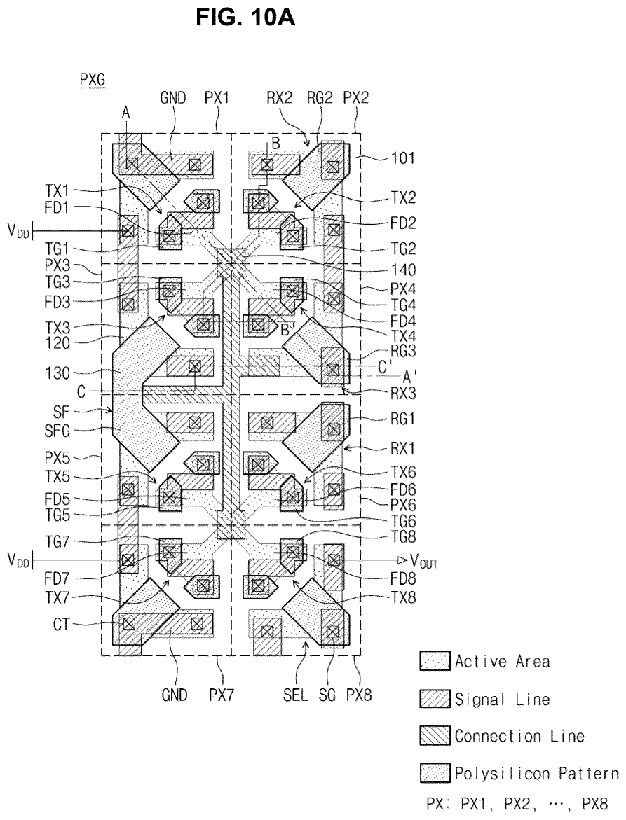

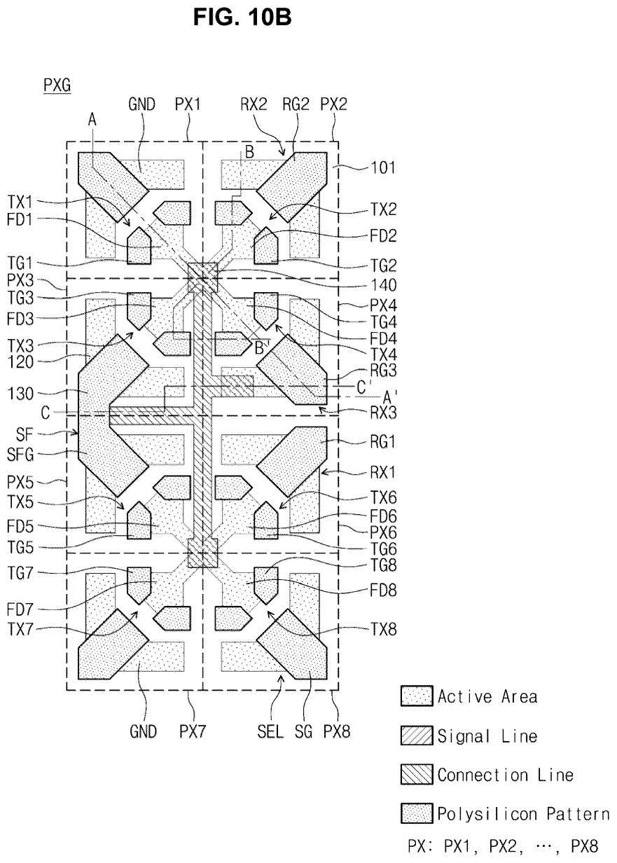

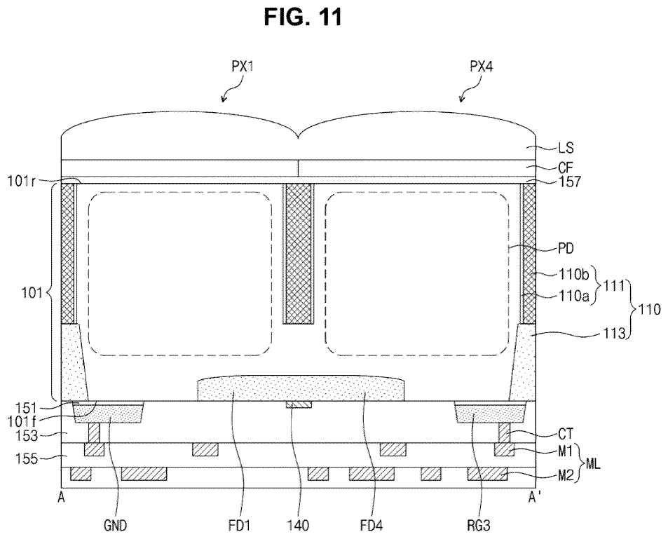

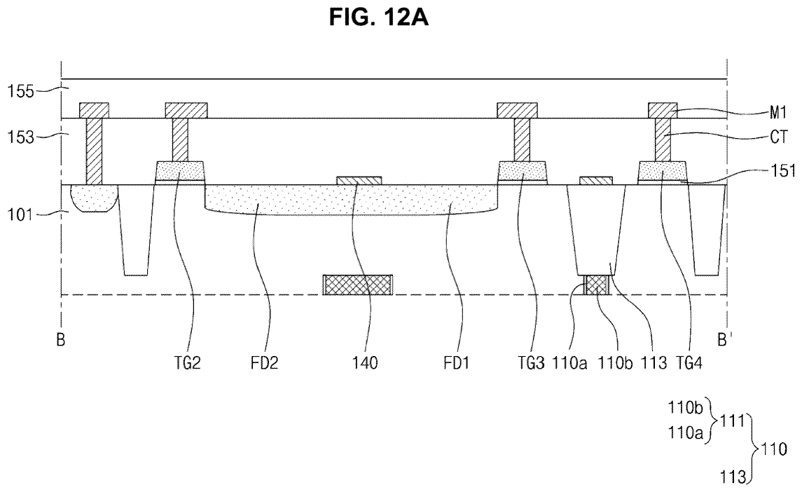

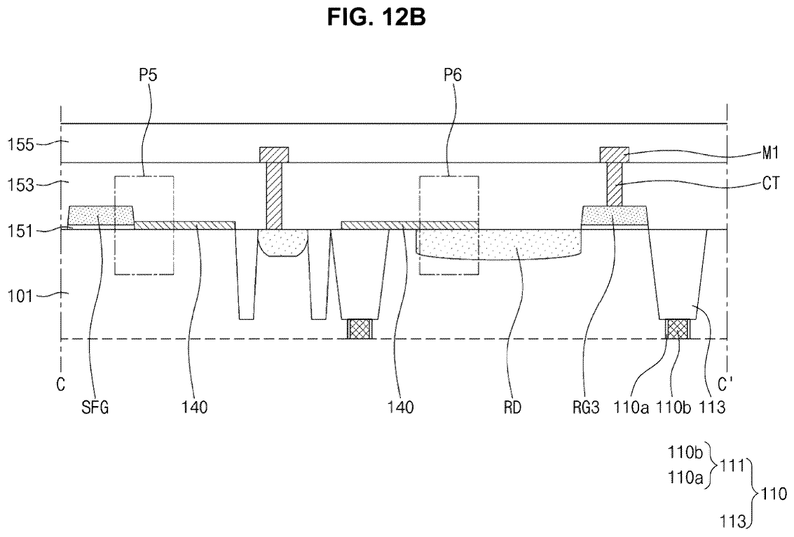

FIG. 10A is a plan view illustrating a pixel group including eight pixels in an image sensor according to an embodiment, and FIG. 10B is a plan view illustrating components of FIG. 10A without some components, for convenience of explanation. FIG. 11 is a cross-sectional view taken along the line A-A′ of FIG. 10A. FIGS. 12A and 12B are cross-sectional views taken along the line B-B′ and the line C-C′ of FIG. 10A, respectively, and illustrate an inverted form without some components of FIG. 10A for convenience of explanation.

Referring to FIGS. 10A, 10B, 11, 12A, and 12B, according to an embodiment, some of the gate, source, drain, ground areas, and floating diffusion areas of transistors in one pixel group PXG are connected to each other through the connection lines 140 and other components are connected to each other through the signal lines ML.

One end portion of the connection line 140 may be connected to the source follower gate SFG by making contact with a side surface of the source follower gate SFG (see, e.g., FIG. 12B). An opposite end portion of the connection line 140 may be connected to the first to eighth floating diffusion areas FD1, FD2, . . . , and FD8 by making contact with a top surface of at least one portion of the first to eighth floating diffusion areas FD1, FD2, . . . , and FD8. Thus, when viewed in a plan view, the one end portion of the connection line 140 may make contact with the boundary of one side of the source follower gate SFG, and the opposite end portion of the connection line 140 may be overlapped with at least one portion of the first to eighth floating diffusion areas FD1, FD2, . . . , and FD8.

According to an embodiment, although the above-described drawing illustrates that the connection line is formed on the semiconductor substrate, a protective layer may be further provided at a lower portion and an upper portion of the connection line.

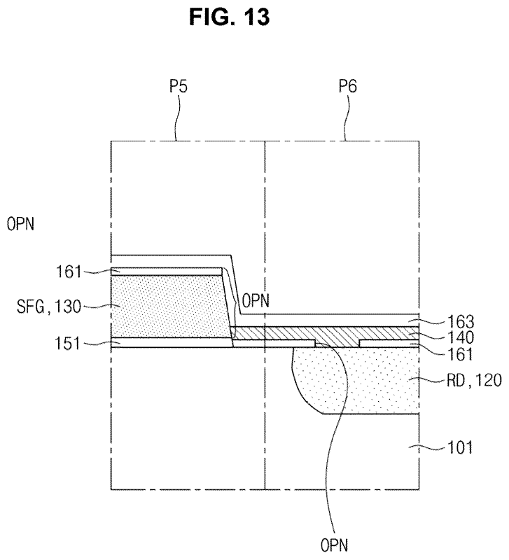

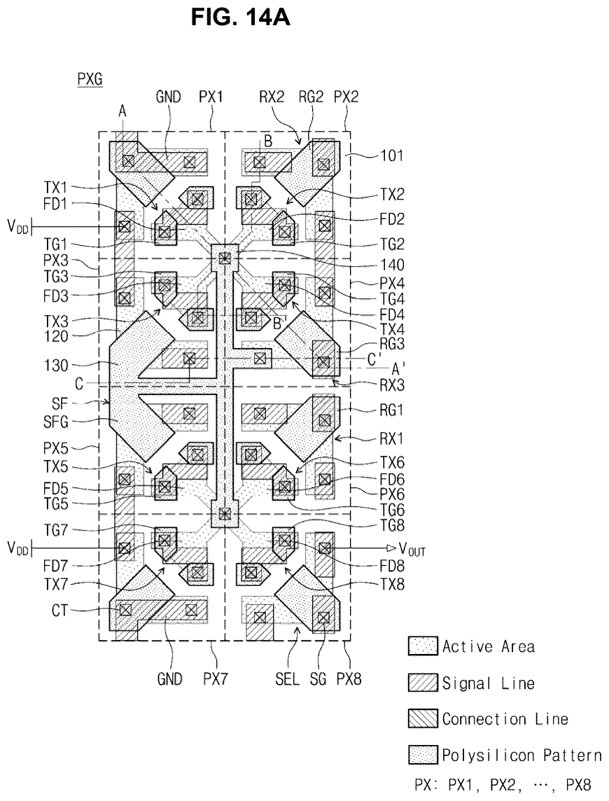

FIG. 13 is cross-sectional views corresponding to parts P5 and P6 of FIG. 12B, and illustrates that the first and second protective layers are provided at a lower portion and an upper portion of the connection line, respectively, according to some embodiments.

Referring to FIG. 13, the first protective layer 161 may be provided on the semiconductor substrate 101 at the source follower gate SFG and at the drain RD of the third reset transistor RX3.

An opening OPN, which exposes a side surface of the source follower gate SFG and a portion of the top surface of the drain RD of the third reset transistor RX3 to the outside, may be provided in the first protective layer 161. For example, the opening OPN may expose the side surface of the source follower gate SFG and the portion of the top surface of the drain RD of the third reset transistor RX3 to the outside. The connection line 140 is provided on the first protective layer 161 having the opening OPN formed therein.

The connection line 140 makes contact with the top surface of the drain RD of the third reset transistor RX3 through the opening OPN, and the side surface of the source follower gate SFG, thereby electrically connecting the source follower gate SFG to the drain RD of the third reset transistor RX3. The second protective layer 163 may be provided on the semiconductor substrate 101 including the connection line 140. For example, in an embodiment, the second protective layer 163 may be provided on the semiconductor substrate 101 to cover the connection line 140.

In the image sensor according to an embodiment, when the lines including transistors are formed, the connection line is formed using a material different from the polysilicon pattern to connect the source follower gate and the floating diffusion area, but embodiments are not limited thereto. For example, the connection line may be formed of the same material as the polysilicon pattern.

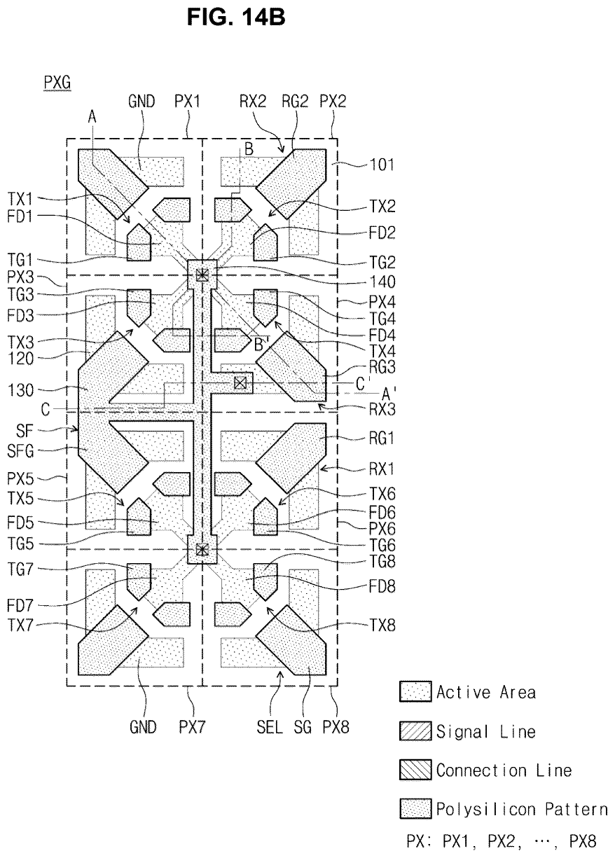

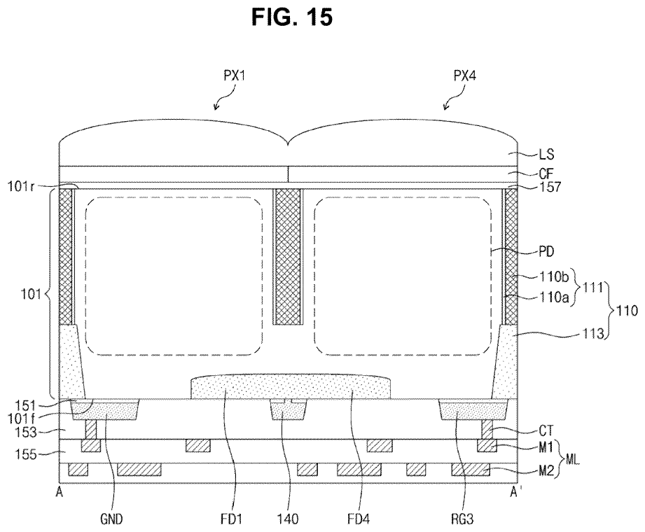

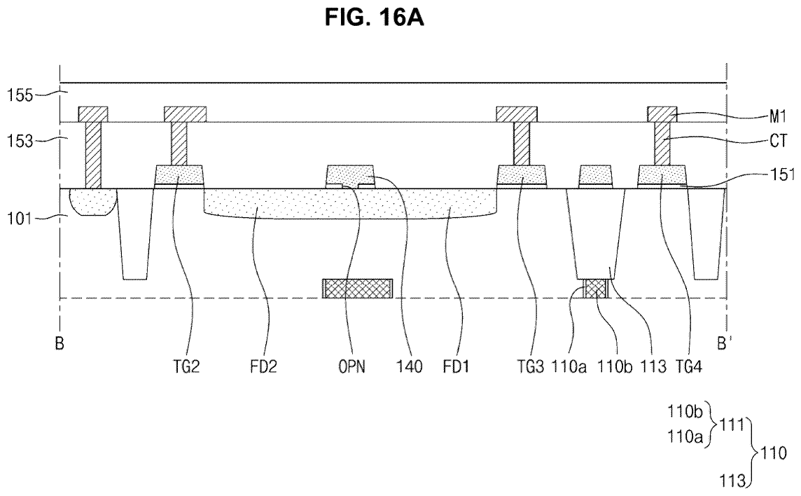

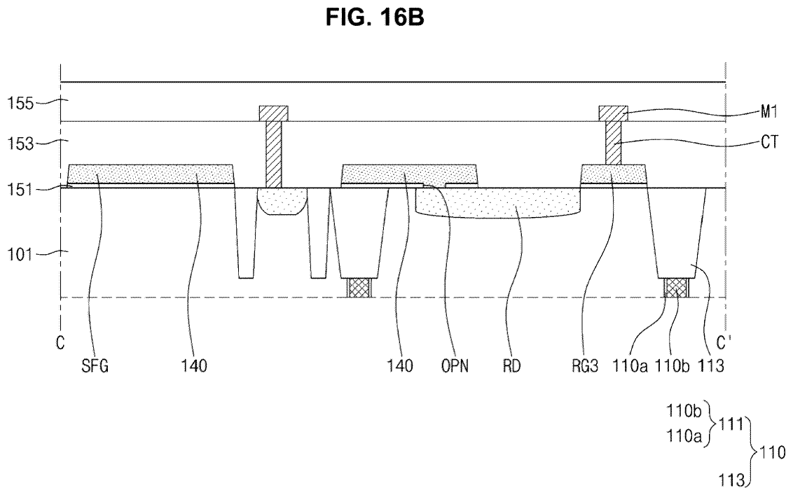

FIG. 14A is a plan view illustrating four pixel groups of an image sensor according to an embodiment, and FIG. 14B is a plan view illustrating components of FIG. 14A without some components for convenience of explanation. FIG. 15 is a cross-sectional view taken along the line A-A′ of FIG. 14A. FIGS. 16A and 16B are cross-sectional views taken along the line B-B′ and the line C-C′ of FIG. 14A, respectively, and illustrate an inverted form without some components of FIG. 14A for convenience of explanation.

Referring to FIGS. 14A, 14B, 15, 16A, and 16B, the source follower gate SFG making contact with the connection line 140 may be formed of the same material. In an embodiment, the source follower gate SFG making contact with the connection line 140 may be formed integrally with the connection line 140 without being separated from the connection line 140 (see, e.g., FIG. 16B). In this case, the source follower gate SFG and the connection line 140 may be simultaneously formed in a single step, rather than being formed separately. The source follower gate SFG may be formed together with the connection line 140 through a single process the same as a process for forming the connection line 140, thereby increasing the degree of freedom in process.

As described above, according to various embodiments, the image sensor employing the interconnection structure is provided to minimize the coupling between the floating diffusion node and the lines adjacent to the floating diffusion node, and to improve the degree of freedom in space for the arrangement of the lines.

The above description refers to various detailed embodiments for carrying out the present disclosure. Embodiments in which a design is changed simply or which are easily changed may be included in the present disclosure as well as an embodiment described above. In addition, technologies that are easily changed and implemented by using the above embodiments may be included in the present disclosure.

While the various embodiments have been described with reference to the drawings, it will be apparent to those of ordinary skill in the art that various changes and modifications may be made thereto without departing from the spirit and scope of the present disclosure as set forth in the following claims.

What is claimed is:

1. An image sensor including a plurality of pixels, the image sensor comprising:
an isolation layer configured to divide the plurality of pixels from each other;
at least one photoelectric conversion device;
at least one floating diffusion area configured to receive a charge from the at least one photoelectric conversion device;
a source follower transistor configured to output a pixel signal corresponding to the charge from the at least one floating diffusion area; and
a connection line configured to connect the at least one floating diffusion area to a gate of the source follower transistor,
wherein the connection line extends from the at least one floating diffusion area to the gate of the source follower transistor, contacts each of the gate of the source follower transistor and the at least one floating diffusion area, and overlaps with at least a portion of the isolation layer.

2. The image sensor of claim 1, wherein at least a portion of the connection line extends in an extending direction of the isolation layer, when viewed in a plan view.

3. The image sensor of claim 2, wherein the at least a portion of the connection line is provided on the isolation layer.

4. The image sensor of claim 2, wherein the at least a portion of the connection line is buried in the isolation layer.

5. The image sensor of claim 4, wherein the isolation layer has a recess part recessed from a top surface of the isolation layer, and the connection line is provided in the recess part.

6. The image sensor of claim 5, further comprising:
a gate insulating layer interposed between the gate of the source follower transistor and the connection line and having a contact hole formed therein,
wherein the connection line is connected to the gate of the source follower transistor through the contact hole.

7. The image sensor of claim 2, wherein a first end portion of the connection line contacts a top surface of the gate of the source follower transistor, and a second end portion of the connection line contacts a top surface of the at least one floating diffusion area.

8. The image sensor of claim 2, wherein a first end portion of the connection line contacts a side surface of the gate of the source follower transistor, and a second end portion of the connection line contacts a top surface of the at least one floating diffusion area.

9. The image sensor of claim 1, further comprising:
a semiconductor substrate including the plurality of pixels,
wherein the at least one floating diffusion area is included in an active area that is doped with impurities in the semiconductor substrate.

10. The image sensor of claim 9, wherein the gate of the source follower transistor includes a polysilicon pattern.

11. The image sensor of claim 10, wherein the connection line is provided integrally with and not being separated from the gate of the source follower transistor.

12. The image sensor of claim 1, further comprising:
at least one reset transistor connected to the at least one floating diffusion area to reset the at least one floating diffusion area to a pixel voltage; and
a selection transistor connected to the source follower transistor to output the pixel signal to an output node.

13. The image sensor of claim 12, wherein the connection line is connected to a drain of the at least one reset transistor by contacting the drain of the at least one reset transistor.

14. The image sensor of claim 12, wherein each gate of the source follower transistor, the selection transistor, and the at least one reset transistor includes a polysilicon pattern.

15. The image sensor of claim 1, wherein at least two pixels, which are adjacent to each other, among the plurality of pixels, constitute one pixel group, and each pixel group includes a plurality of floating diffusion areas.

16. The image sensor of claim 15, wherein the connection line is formed in one line and extends, without being separated into segments, from the gate of the source follower transistor to each of the plurality of floating diffusion areas.

17. The image sensor of claim 1, wherein the at least one floating diffusion area includes first to eighth floating diffusion areas.

18. The image sensor of claim 1, further comprising:
a semiconductor substrate including the plurality of pixels;
a first interlayer insulating layer provided on the semiconductor substrate;
a signal line provided on the first interlayer insulating layer; and
a plurality of contact parts formed through the first interlayer insulating layer and connected to the signal line.

19. An image sensor having at least two pixel groups, each including a plurality of pixels, the at least two pixel groups being arranged in a form of a matrix, the image sensor comprising:
an isolation layer configured to divide the plurality of pixels from each other;
a plurality of photoelectric conversion devices provided in the plurality of pixels, respectively;
at least one floating diffusion area configured to receive a charge from each of the plurality of photoelectric conversion devices;
at least one reset transistor connected to the at least one floating diffusion area to reset the at least one floating diffusion area to a pixel voltage;
a source follower transistor configured to output a pixel signal corresponding to the charge from the at least one floating diffusion area; and
a connection line configured to connect the at least one floating diffusion area to a gate of the source follower transistor,
wherein the connection line extends in one line without being separated into segments to connect the at least one floating diffusion area, the gate of the source follower transistor, and a drain of the at least one reset transistor to each other, contacts each of the at least one floating diffusion area, the gate of the source follower transistor, and the drain of the at least one reset transistor, and overlaps with at least a portion of the isolation layer.

20. An image sensor including at least one pixel group provided in a form of a matrix and including first to eighth pixels, the image sensor comprising:
first to eighth photoelectric conversion devices provided in the first to eighth pixels, respectively;
a floating diffusion area configured to receive a charge from the first to eighth photoelectric conversion devices;
first to third reset transistors connected to the floating diffusion area to reset the floating diffusion area to a pixel voltage;
a source follower transistor connected to the floating diffusion area to output a pixel signal corresponding to the charge from the floating diffusion area;
a selection transistor connected to the source follower transistor, to output the pixel signal to an output node; and
a connection line configured to connect the source follower transistor to the floating diffusion area,
wherein the floating diffusion area includes:
first to eighth floating diffusion areas provided in the first to eighth pixels, respectively, and
wherein the connection line contacts with at least one of the first to eighth floating diffusion areas and a gate of the source follower transistor to connect the gate of the source follower transistor to the at least one of the first to eighth floating diffusion areas.
